(19) United States
(12) Patent Application Publication
(10) Pub. No.: US 2026/0011686 A1
(43) Pub. Date: Jan. 8, 2026

(54) HIGH DIE STACK PACKAGE WITH SECONDARY INTERPOSER

(71) Applicant: Micron Technology, Inc., Boise, ID (US)

(72) Inventors: Seng Kim Ye, Singapore (SG); Kelvin Tan Aik Boo, Singapore (SG); Hong Wan Ng, Singapore (SG); Chin Hui Chong, Singapore (SG)

(21) Appl. No.: 19/260,096

(22) Filed: Jul. 3, 2025

Related U.S. Application Data
(60) Provisional application No. 63/668,758, filed on Jul. 8, 2024.

(51) Int. Cl. H01L 25/04; H01L 23/00; H01L 23/31

(52) U.S. Cl. CPC H01L 25/04; H01L 23/3107; H01L 24/48; H01L 2224/48145; H01L 2224/48225; H01L 2225/06562

(57) ABSTRACT

Systems, devices, and methods for high die stack packages with secondary interposers are provided herein. A die stack package can include a first substrate, a first die stack carried by the first substrate, a second die stack carried by the first substrate, a second substrate carried by the first die stack and the second die stack, a third die stack carried by the second substrate, a fourth die stack carried by the second substrate, and one or more vertical wires electrically coupling the first substrate and the second substrate. Each of the first, second, third, and fourth die stacks can include a plurality of dies stacked in a cascading arrangement. In some embodiments, the first and second die stacks are each electrically coupled to the first substrate. In some embodiments, the first and second die stacks are each electrically coupled to the second substrate.

### CROSS-REFERENCE TO RELATED APPLICATION(S)

The present application claims priority to U.S. Provisional Patent Application No. 63/668,758, filed Jul. 8, 2024, the disclosure of which is incorporated herein by reference in its entirety.

### TECHNICAL FIELD

The present disclosure generally relates to semiconductor device assemblies, and more particularly relates to high die stack packages with secondary interposers.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1A is a partially schematic cross-sectional diagram of a die stack package including two die stacks.

FIG. 1B is a partially schematic cross-sectional diagram of a die stack package including four die stacks.

FIG. 2 is a partially schematic cross-sectional diagram of a die stack package configured in accordance with embodiments of the present technology.

FIG. 3 is a partially schematic plan view of an input-and-output extender configured in accordance with embodiments of the present technology.

FIG. 4 is a partially schematic cross-sectional diagram of another die stack package configured in accordance with embodiments of the present technology.

FIG. 5 is a partially schematic cross-sectional diagram of yet another die stack package configured in accordance with embodiments of the present technology.

FIG. 6 is a flowchart illustrating a method for manufacturing a die stack package in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

The demand for more dies in semiconductor packages is driven by the increasing need for higher performance, greater functionality, and improved energy efficiency in modern electronic devices. As applications in fields like artificial intelligence, high-performance computing, and mobile technology evolve, the necessity for integrating more computational power, more memory and/or storage, and specialized functions within a single package has grown significantly. However, as more dies are integrated into a single package, the physical space occupied by semiconductor packages and the necessary interconnections between dies become more problematic. This can lead to challenges in maintaining signal integrity, managing thermal dissipation, and ensuring reliable power delivery. Additionally, as the package becomes denser, the complexity of routing signals between the dies and the external connections increases.

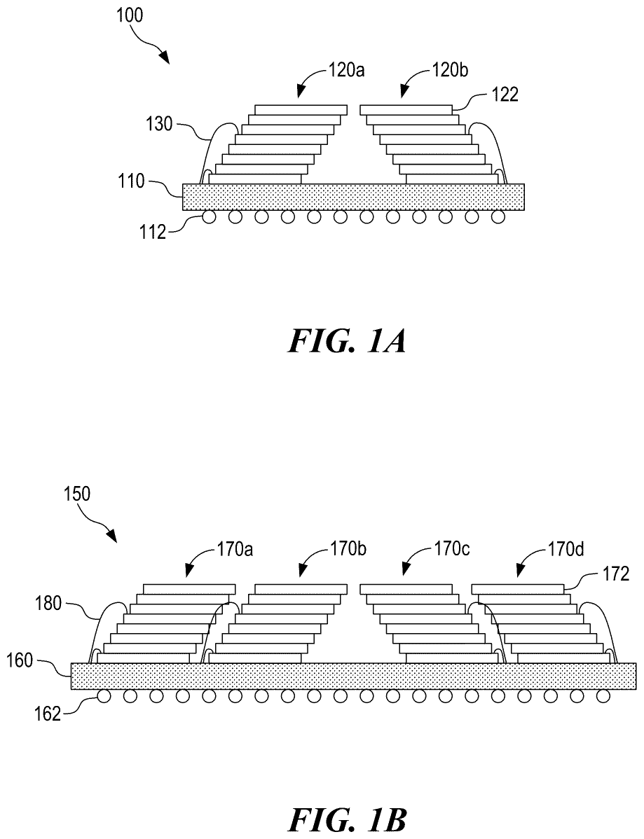

FIG. 1A is a partially schematic cross-sectional diagram of a die stack package 100. The die stack package 100 includes a substrate 110, a first die stack 120a, and a second die stack 120b. The substrate 110 can be coupled to other components not shown (e.g., a package substrate) via interconnections 112 (e.g., solder balls) such that the die stack package 100 can form part of a system-in-package (SiP). Each of the first die stack 120a and the second die stack 120b is carried by the substrate 110 such that the first die stack 120a and the second die stack 120b are arranged side-by-side. The first die stack 120a and the second die stack 120b can each include a plurality of dies 122 (in the illustrated embodiment, each die stack includes eight dies) stacked on top of one another in a cascading arrangement (e.g., forming steps), as illustrated. Also, one or more of the dies 122 in each of the first die stack 120a and the second die stack 120b can be electrically coupled to the substrate 110 via corresponding wire bonds 130. In particular, the wire bonds 130 can be coupled to portions of the upper surfaces of the one or more dies 122 that are exposed by virtue of the cascading arrangement.

FIG. 1B is a partially schematic cross-sectional diagram of a die stack package 150. The die stack package 150 includes a substrate 160, a first die stack 170a, a second die stack 170b, a third die stack 170c, and a fourth die stack 170d. The substrate 160 can be coupled to other components not shown (e.g., a package substrate) via interconnections 162 (e.g., solder balls) such that the die stack package 150 can form part of a system-in-package (SiP). Each of the first through fourth die stacks 170a-d is carried by the substrate 160 such that the first through fourth die stacks 170a-d are arranged side-by-side. The first through fourth die stacks 170a-d can each include a plurality of dies 172 (in the illustrated embodiment, each die stack includes eight dies) stacked on top of one another in a cascading arrangement (e.g., forming steps), as illustrated. Also, one or more of the dies 172 in each of the first through fourth die stacks 170a-d can be electrically coupled to the substrate 160 via corresponding wire bonds 180. In particular, the wire bonds 180 can be coupled to portions of the upper surfaces of the one or more dies 172 that are exposed by virtue of the cascading arrangement.

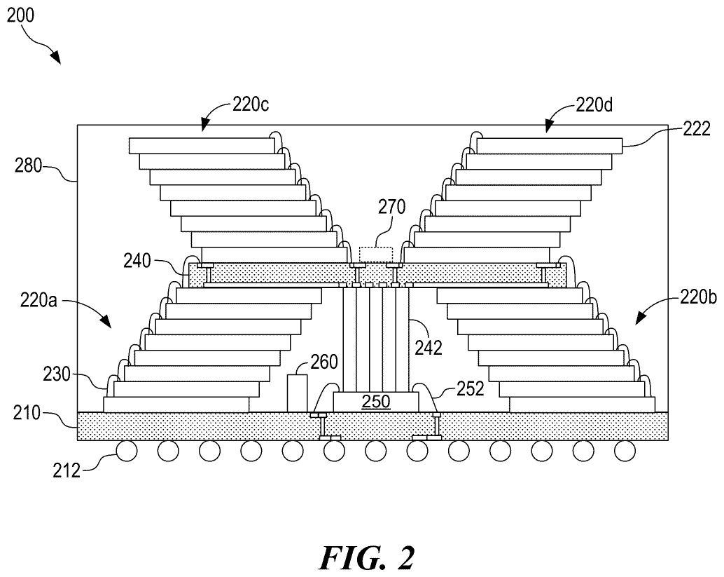

Comparing the die stack package 150 (FIG. 1B) to the die stack package 100 (FIG. 1A), the substrate 160 has a greater lateral dimension (e.g., length, width) than the substrate 110 in order to accommodate double the number of die stacks carried thereon. However, SiPs may not be able to accommodate die stack packages with increased x-y form factors given space constraints. Additionally or alternatively, die stack packages with large lateral dimensions may impose undue constraints on other components of the SiP. Moreover, if a die stack package were to include a greater number of die stacks (e.g., eight, sixteen, etc.), continuously expanding the lateral dimension of the substrate thereof can be impractical. Merely stacking the first die stack 170a on the second die stack 170b and stacking the fourth die stack 170d on the third die stack 170c to continue the cascading arrangement upward would also be impossible. While this can seemingly keep the lateral dimension of the substrate 160 equal to that of the substrate 110, because the first and fourth die stacks 170a cascade upward and toward one another, the first and fourth die stacks 170a would need to occupy the same space. To address these problems and others, embodiments of the present technology provide high die stack packages with secondary interposers, as illustrated in and discussed below with reference to FIGS. 2-6.

FIG. 2 is a partially schematic cross-sectional diagram of a die stack package 200 configured in accordance with embodiments of the present technology. The die stack package 200 includes a first substrate 210 (also referred to herein as “the main substrate,” “the first interposer,” “the main interposer,” “the primary substrate,” “the primary interposer”), a second substrate 240 (also referred to herein as “the secondary substrate,” “the second interposer,” “the secondary interposer”), and first through fourth die stacks 220a-d. The die stack package 200 further includes an input-and-output extender (“IOE”) 250, a first semiconductor structure 260, a second semiconductor structure 270, and an encapsulant 280.

The first substrate 210 can be coupled to other components not shown (e.g., a package substrate) via interconnections 212 (e.g., solder balls) such that the die stack package 200 can form part of a system-in-package (SiP). The first die stack 220a and the second die stack 220b are carried by the first substrate 210 such that the first die stack 220a and the second die stack 220b are arranged side-by-side. The second substrate 240 is stacked on top of the first die stack 220a and the second die stack 220b, and the third die stack 220c and the fourth die stack 220d are carried by the second substrate 240 such that the third die stack 220c and the fourth die stack 220d are arranged side-by-side. As discussed further herein, the first substrate 210 and the second substrate 240 are electrically coupled via vertical wires 242.

Each of the first through fourth die stacks 220a-d includes a plurality of dies 222 (in the illustrated embodiment, each die stack includes eight dies) stacked on top of one another in a cascading arrangement (e.g., forming steps), as illustrated. In particular, the dies 222 of the first die stack 220a and the dies 222 of the second die stack 220b cascade upward and toward one another (e.g., toward the vertical wires 242), and the dies 222 of the third die stack 220c and the dies 222 of the fourth die stack 220d cascade upward and away from one another (e.g., away from the vertical wires 242). The dies 222 can include volatile memory dies (e.g., DRAM dies, LPDRAM dies), non-volatile memory dies (e.g., NAND dies, NOR dies, PCM dies, FeRAM dies, MRAM dies), ASIC dies, IOE dies, controller dies, and/or any other suitable dies.

In each die stack, adjacent dies 222 are electrically coupled to one another via corresponding wire bonds 230. The wire bonds 230 can be coupled to portions of the upper surfaces of the dies 222 that are exposed by virtue of the cascading arrangement. Thus, the wire bonds 230 are arranged on the sides of the first and second die stacks 220a, 220b facing away from the vertical wires 242, and are arranged on the sides of the third and fourth die stacks 220c, 220d facing toward the vertical wires 242. Notably, in the illustrated embodiment of FIG. 2, the wire bonds 230 electrically couple each of the first and second die stacks 220a, 220b to the second substrate 240 (e.g., to bond pads thereof), but not to the first substrate 210. Also, the wire bonds 230 electrically couple each of the third and fourth die stacks 220c, 220d to the second substrate 240 (e.g., to bond pads thereof).

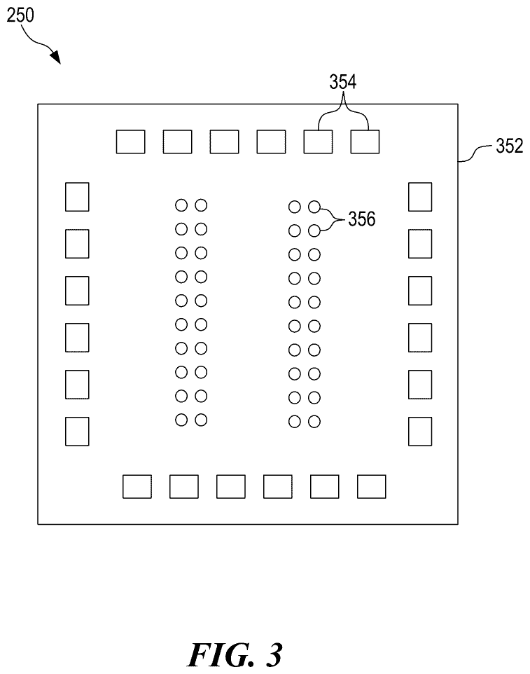

The IOE 250 (also referred to as “the multiplexer”) is carried by the first substrate 210 and positioned in the space between the first and second die stacks 220a, 220b. The IOE 250 can be electrically coupled to the first substrate 210 (e.g., to bond pads thereof) via IOE wire bonds 252, and can be electrically coupled to the second substrate 240 via the vertical wires 242. Referring momentarily to FIG. 3, FIG. 3 is a partially schematic plan view of the IOE 250 configured in accordance with embodiments of the present technology. The IOE 250 can include a base 352, one or more first bond pads 354 on the base 352, and one or more second bond pads 356 on the base 352. The first bond pads 354 can be arranged along a periphery of the base 352, as shown, and can be shaped and sized to be coupleable to the IOE wire bonds 252 (FIG. 2). The second bond pads 356 can be arranged toward the center of the base 352, and can be shaped and sized to be coupleable to the vertical wires 242 (FIG. 2). Therefore, returning to FIG. 2, the IOE 250, the IOE wire bonds 252, and the vertical wires 242 electrically couple the first substrate 210 to the second substrate 240. Also, the wire bonds 230 electrically couple the second substrate 240 to the first through fourth die stacks 220a-d. Therefore, the first substrate 210 (and thus other components coupled thereto) is electrically coupled to each of the dies 222 included in the first through fourth die stacks 220a-d.

The first semiconductor structure 260 is carried by the first substrate 210, positioned in the space between the first and second die stacks 220a, 220b, and arranged side-by-side with the IOE 250. The first semiconductor structure 260 can include an Application-Specific Integrated Circuit (ASIC), a capacitor, an inductor, and/or the like. The second semiconductor structure 270 is carried by the second substrate 240 and positioned in the space between the third and fourth die stacks 220c, 220d. The second semiconductor structure 270 can be electrically coupled to the second substrate 240 (e.g., to bond pads thereof). The second semiconductor structure 270 can include an ASIC, a capacitor, an inductor, another IOE, and/or the like. The encapsulant 280 can be disposed over and/or around the first substrate 210 to protect and maintain the arrangement of the components of the die stack package 200.

By including the second substrate 240, the die stack package 200 can stack the third and fourth die stacks 220c, 220d vertically above the first and second die stacks 220a, 220b, respectively. In particular, the second substrate 240 provides the necessary interconnection points (e.g., bond pads) for electrically coupling the other components of the die stack package 200 to one another. Also, as aforementioned, the third and fourth die stacks 220c, 220d are arranged to cascade upward and away from the vertical wires 242. Therefore, the lateral dimension of the first substrate 210, which defines the lateral dimension of the die stack package 200, can be smaller than, for example, the lateral dimension of the substrate 160 (FIG. 1B) while the die stack package 200 includes the same number of dies (e.g., 32 dies, as shown) and die stacks (e.g., 4 die stacks, as shown). Moreover, the vertical wires 242 provide an effective and efficient solution to electrically couple the first substrate 210 to the second substrate 240 (and thus other components of the die stack package 200) regardless of the height of the die stacks (e.g., regardless of the distance between the first substrate 210 and the second substrate 240).

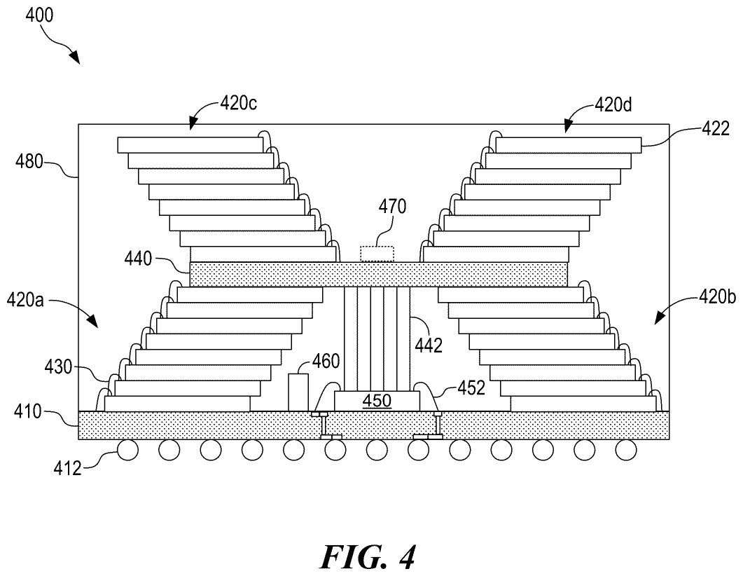

FIG. 4 is a partially schematic cross-sectional diagram of a die stack package 400 configured in accordance with embodiments of the present technology. The die stack package 400 can be generally similar to the die stack package 200 of FIG. 2. For example, the die stack package 400 includes a first substrate 410 (also referred to herein as “the main substrate,” “the first interposer,” “the main interposer,” “the primary substrate,” “the primary interposer”), a second substrate 440 (also referred to herein as “the secondary substrate,” “the second interposer,” “the secondary interposer”), and first through fourth die stacks 420a-d. The die stack package 400 further includes an input-and-output extender (“IOE”) 450, a first semiconductor structure 460, a second semiconductor structure 470, and an encapsulant 480. Components of the die stack package 400 can be identical or generally similar in structure and/or function as components of the die stack package 200 of FIG. 2 that are similarly labeled, unless indicated otherwise.

The first substrate 410 can be coupled to other components not shown (e.g., a package substrate) via interconnections 412 (e.g., solder balls) such that the die stack package 400 can form part of a system-in-package (SiP). Each of the first through fourth die stacks 420a-d includes a plurality of dies 422 stacked in a cascading arrangement (e.g., forming steps). Adjacent dies 422 are electrically coupled to one another via wire bonds 430. The IOE 450 can be electrically coupled to the first substrate 410 (e.g., to bond pads thereof) via IOE wire bonds 452, and can be electrically coupled to the second substrate 440 via vertical wires 442.

Unlike in the die stack package 200, however, the wire bonds 430 electrically couple the first substrate 410 to the two dies 422 of the first and second die stacks 420a, 420b immediately carried by the first substrate 410, as shown. Also, unlike in the die stack package 200, the wire bonds 430 do not electrically couple the second substrate 440 to the two dies 422 of the first and second die stacks 420a, 420b immediately below the second substrate 440. Therefore, in some embodiments, the dies 422 of the third and fourth die stacks 420c, 420d immediately carried by the second substrate 440 can be positioned generally flush with the edges of the second substrate 440, since no portion of the upper surface of the second substrate 440 need be exposed for coupling to one of the wire bonds 430.

Therefore, the first substrate 410 (and thus other components coupled thereto) is electrically coupled to the first and second die stacks 420a, 420b via the wire bonds 430 and to the third and fourth die stacks 420c, 420d via the IOE wire bonds 452, the IOE 450, the vertical wires 442, the second substrate 440, and the wire bonds 430. While FIGS. 2 and 4 each illustrate the first and second die stacks directly coupled to only one of the first substrate or the second substrate via wire bonds, one of ordinary skill in the art will appreciate that in some embodiments, the first and/or second die stacks are directly coupled to the first substrate and the second substate via wire bonds.

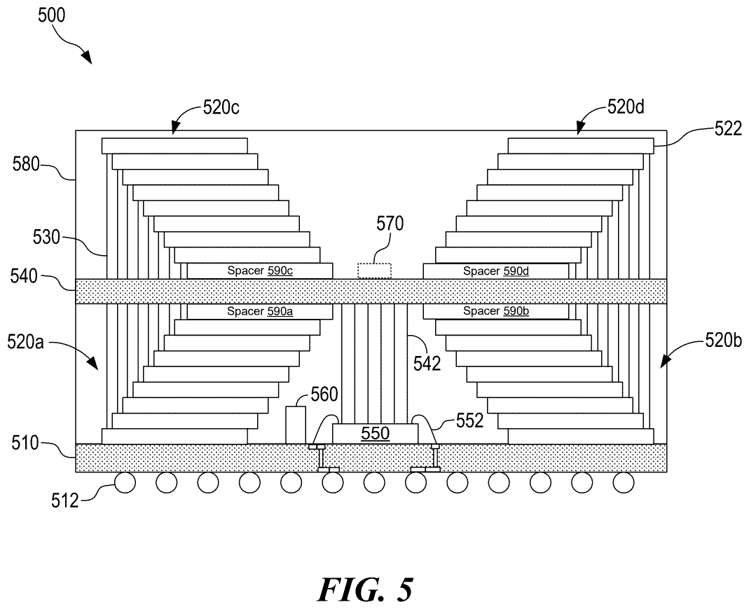

FIG. 5 is a partially schematic cross-sectional diagram of a die stack package 500 configured in accordance with embodiments of the present technology. The die stack package 500 can be generally similar to the die stack package 200 of FIG. 2. For example, the die stack package 500 includes a first substrate 510 (also referred to herein as “the main substrate,” “the first interposer,” “the main interposer,” “the primary substrate,” “the primary interposer”), a second substrate 540 (also referred to herein as “the secondary substrate,” “the second interposer,” “the secondary interposer”), first through fourth die stacks 520a-d, and first through fourth spacers 590a-d. The die stack package 500 further includes an input-and-output extender (“IOE”) 550, a first semiconductor structure 560, a second semiconductor structure 570, and an encapsulant 580. Components of the die stack package 500 can be identical or generally similar in structure and/or function as components of the die stack package 200 of FIG. 2 that are similarly labeled, unless indicated otherwise.

The first substrate 510 can be coupled to other components not shown (e.g., a package substrate) via interconnections 512 (e.g., solder balls) such that the die stack package 500 can form part of a system-in-package (SiP). Each of the first through fourth die stacks 520a-d includes a plurality of dies 522 stacked in a cascading arrangement (e.g., forming steps). The IOE 550 can be electrically coupled to the first substrate 510 (e.g., to bond pads thereof) via IOE wire bonds 552, and can be electrically coupled to the second substrate 540 via vertical wires 542. In some embodiments, a relatively thin layer of the encapsulant 580 is disposed above the uppermost dies 522 of the third and fourth die stacks 520c, 520d given the lack of any wire bond or other structure thereon. In some embodiments, the upper surfaces of the uppermost dies 522 of the third and fourth die stacks 520c, 520d are exposed (e.g., not covered by the encapsulant 580). The relatively thin layer of the encapsulant 580, or lack thereof, on the uppermost dies 522 of the third and fourth die stacks 520c, 520d can facilitate efficient cooling of the die stacks.

Unlike in the die stack package 200, however, the dies 522 are not coupled to one another, and are instead each coupled to the second substrate 540 via corresponding ones of a plurality of vertical die wires 530. As illustrated in FIG. 5, the vertical die wires 530 extend between the second substrate 540 and (i) the exposed upper surface portions of the dies 522 of the first die stack 520a, (ii) the exposed upper surface portions of the dies 522 of the second die stack 520b, (iii) the exposed lower surface portions of the dies 522 of the third die stack 520c, and (iv) the exposed lower surface portions of the dies 522 of the fourth die stack 520d. Thus, the vertical die wires 530 can extend vertically (e.g., through the encapsulant 580) parallel to one another.

Also, unlike in the die stack package 200, the second substrate 540 does not directly contact the first through fourth die stacks 520a-d. Instead, the first through fourth spacers 590a-d are stacked between the second substrate 540 and corresponding ones of the first through fourth die stacks 520a-d. As shown, the first through fourth spacers 590a-d provide space for the vertical die wires 530 to extend between the second substrate 540 and the die 522 of each of the first through fourth die stacks 520a-d closest to the second substate 540. Therefore, the second substrate 540 is directly coupled to each of the dies 522 of the first through fourth die stacks 520a-d via the vertical die wires 530, and the first substrate 510 (and thus other components coupled thereto) is electrically coupled to the second substrate 540 via the IOE wire bonds 552, the IOE 550, and the vertical wires 542.

Referring to FIGS. 2-5 together, embodiments of the present technology provide a scalable die stack package that can include more than four die stacks. For example, in some embodiments, the die stack package includes a third substrate stacked on top of the third and fourth die stacks, and fifth and sixth die stacks stacked on top of the third substrate. In some embodiments, the die stack package further includes a fourth substrate stacked on top of the fifth and sixth die stacks, and seventh and eighth die stacks stacked on top of the fourth substrate. Thus, one of ordinary skill in the art will appreciate that die stack packages configured in accordance with embodiments of the present technology can include a wide range of number of dies and die stacks while maintaining an x-y form factor smaller than that of conventional packages including the same number of dies and die stacks (e.g., the die stack package 150 of FIG. 1B).

Die stack packages configured in accordance with embodiments of the present technology also provide high manufacturability, electrical reliability, and thermal management. First, the die stack packages illustrated and described herein can be manufactured with commonly available and/or easily modifiable components, such as wires and interposers. Second, the electrical signals are communicated to and from the dies directly through the first substrate and/or through the IOE, thereby maintaining the integrity of the signals. Third, the uppermost dies can be exposed (e.g., not fully covered) or covered with a relatively thin layer of the encapsulant, thereby allowing the die stacks to cool off more quickly and efficiently than die stack packages with a relatively thick layer of the encapsulant. This can be particularly true for the die stack package 500 of FIG. 5 because unlike the die stack package 200 of FIG. 2 and the die stack package 400 of FIG. 4, the die stack package 500 does not include wire bonds extending above the uppermost dies, which can require encapsulation by the encapsulant.

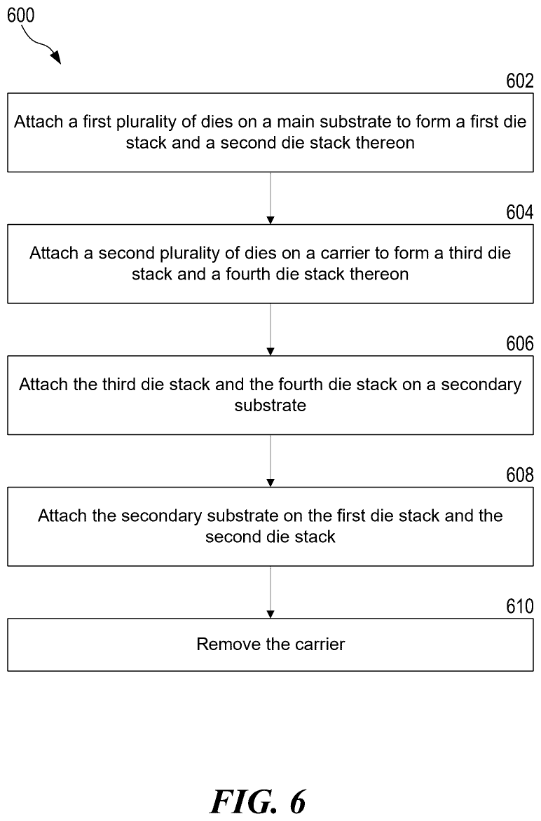

FIG. 6 is a flowchart illustrating a method 600 for manufacturing a die stack package in accordance with some embodiments of the present technology. While the steps of the method 600 are described below in a particular order, one or more of the steps can be performed in a different order or omitted, and the method 600 can include additional and/or alternative steps. Additionally, although the method 600 may be described below with reference to the embodiments of the present technology described herein, the method 600 can be performed with other embodiments of the present technology.

The method 600 begins at block 602 by attaching a first plurality of dies on a main substrate (e.g., the first substrate 210 of FIG. 2) to form a first die stack (e.g., the first die stack 220a) and a second die stack (e.g., the second die stack 220b). In some embodiments, attaching the first plurality of dies on the main substrate comprises electrically coupling, via wire bonds (e.g., the wire bonds 230), each of the dies of the first die stack and the second die stack to adjacent ones of the dies. In some embodiments, attaching the first plurality of dies on the main substrate comprises electrically coupling, via wire bonds, each of the first die stack and the second die stack to the main substrate.

At block 604, the method 600 continues by attaching a second plurality of dies on a carrier to form a third die stack (e.g., the third die stack 220c) and a fourth die stack (e.g., the fourth die stack 220d). The carrier can include a wafer carrier, a tape carrier, a gel-pack carrier, a ceramic carrier, a flip-chip carrier, and/or the like.

At block 606, the method 600 continues by attaching the third die stack and the fourth die stack on a secondary substrate (e.g., the second substrate 240). In some embodiments, attaching the third die stack and the fourth die stack on the secondary substrate comprises electrically coupling, via wire bonds, (i) each of the dies of the third die stack and the fourth die stack to adjacent ones of the dies and (ii) each of the third die stack and the fourth die stack to the secondary substrate. In some embodiments, attaching the third die stack and the fourth die stack on the secondary substrate comprises electrically coupling, via vertical wires, each of the dies of the third die stack and the fourth die stack to the secondary substrate.

At block 608, the method 600 continues by attaching the secondary substrate on the first die stack and the second die stack. In some embodiments, attaching the secondary substrate on the first die stack and the second die stack comprises electrically coupling, via wire bonds, each of the first die stack and the second die stack to the secondary substrate. In some embodiments, attaching the secondary substrate on the first die stack and the second die stack comprises electrically coupling, via vertical wires, each of the dies of the first die stack and the second die stack to the secondary substrate.

At block 610, the method 600 continues by removing the carrier. As noted above, the carrier can include various types of carriers and the process of removing the carrier can depend accordingly. In some embodiments, the method 600 further comprises encapsulating the structure including the first through fourth die stacks in an encapsulant (e.g., the encapsulant 280). In some embodiments, the method 600 further comprises attaching interconnections (e.g., the interconnections 212) to the main substrate. In some embodiments, the method 600 further comprises marking, singulation, and/or the like.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

I/We claim:

1. A die stack package, comprising:
a first substrate;
a first die stack carried by the first substrate;
a second die stack carried by the first substrate;
a second substrate carried by the first die stack and the second die stack;
a third die stack carried by the second substrate;
a fourth die stack carried by the second substrate, wherein each of the first, second, third, and fourth die stacks includes a plurality of dies stacked in a cascading arrangement; and
one or more vertical wires electrically coupling the first substrate and the second substrate.

2. The die stack package of claim 1, wherein the dies of each of the first die stack and the second die stack are arranged to cascade upward and toward the vertical wires, and wherein the dies of each of the third die stack and the fourth die stack are arranged to cascade upward and away from the vertical wires.

3. The die stack package of claim 1, further comprising wire bonds electrically coupling (i) each of the dies of each of the first, second, third, and fourth die stacks to adjacent ones of the dies and (ii) the second substrate to each of the first, second, third, and fourth die stacks.

4. The die stack package of claim 1, further comprising wire bonds electrically coupling (i) each of the dies of each of the first, second, third, and fourth die stacks to adjacent ones of the dies, (ii) the first substrate to each of the first and second die stacks, and (iii) the second substrate to each of the third and fourth die stacks.

5. The die stack package of claim 1, further comprising a plurality of vertical die wires electrically coupling the second substrate to individual ones of the dies of the first, second, third, and fourth die stacks.

6. The die stack package of claim 5, further comprising an encapsulant around the first, second, third, and fourth die stacks, wherein uppermost dies of the third and fourth die stacks are not fully covered by the encapsulant.

7. The die stack package of claim 5, further comprising:
a first spacer stacked between the first die stack and the second substrate;
a second spacer stacked between the second die stack and the second substrate;
a third spacer stacked between the third die stack and the second substrate; and
a fourth spacer stacked between the fourth die stack and the second substrate,
wherein the first, second, third, and fourth spacers are configured to provide space for the vertical die wires to extend between the second substrate and each of the dies of the first, second, third, and fourth die stacks closest to the second substrate, respectively.

8. The die stack package of claim 1, further comprising an input-and-output extender (IOE) carried by the first substrate, wherein the IOE is electrically coupled to the first substrate via IOE wire bonds and electrically coupled to the second substrate via the one or more vertical wires.

9. The die stack package of claim 8, wherein the IOE comprises a base, a plurality of first bond pads positioned along a periphery of the base and coupleable to the IOE wire bonds, and a plurality of second bond pads positioned around a center of the base and coupleable to the one or more vertical wires.

10. The die stack package of claim 1, further comprising a semiconductor structure carried by the first substrate and positioned between the first and second die stacks, wherein the semiconductor structure includes an Application-Specific Integrated Circuit (ASIC), a capacitor, or an inductor.

11. The die stack package of claim 1, further comprising a semiconductor structure carried by the second substrate and positioned between the third and fourth die stacks, wherein the semiconductor structure includes an Application-Specific Integrated Circuit (ASIC), an input-and-output extender (IOE), a capacitor, or an inductor.

12. The die stack package of claim 1, further comprising:
a third substrate carried by the third and fourth die stacks;
a fifth die stack carried by the third substrate; and
a sixth die stack carried by the third substrate, wherein each of the fifth and sixth die stacks includes a plurality of dies stacked in a cascading arrangement.

13. The die stack package of claim 1, wherein each of the first, second, third, and fourth die stacks includes eight dies.

14. A die stack package, comprising:
a main substrate;
a first die stack carried by the main substrate;
a second die stack carried by the main substrate, wherein the first and second die stacks cascade upward and toward one another;
a secondary substrate carried by the first die stack and the second die stack;
a third die stack carried by the secondary substrate; and
a fourth die stack carried by the secondary substrate, wherein the third and fourth die stacks cascade upward and away from one another.

15. The die stack package of claim 14, further comprising an input-and-output extender (IOE) carried by the main substrate, wherein the IOE is electrically coupled to the main substrate via IOE wire bonds and electrically coupled to the secondary substrate via one or more vertical wires extending therebetween.

16. A method for manufacturing a die stack package, the method comprising:
attaching a first plurality of dies on a main substrate to form a first die stack and a second die stack thereon;
attaching a second plurality of dies on a carrier to form a third die stack and a fourth die stack thereon;
attaching the third die stack and the fourth die stack on a secondary substrate;
attaching the secondary substrate on the first die stack and the second die stack; and
removing the carrier.

17. The method of claim 16, wherein attaching the first plurality of dies on the main substrate comprises electrically coupling, via wire bonds, (i) each of the dies of the first die stack and the second die stack to adjacent ones of the dies, and (ii) each of the first die stack and the second die stack to the main substrate.

18. The method of claim 16, wherein attaching the first plurality of dies on the main substrate comprises electrically coupling, via first wire bonds, each of the dies of the first die stack and the second die stack to adjacent ones of the dies, and wherein attaching the secondary substrate on the first die stack and the second die stack comprises electrically coupling, via second wire bonds, each of the first die stack and the second die stack to the secondary substrate.

19. The method of claim 16, wherein attaching the third die stack and the fourth die stack on the secondary substrate comprises electrically coupling, via wire bonds, (i) each of the dies of the third die stack and the fourth die stack to adjacent ones of the dies, and (ii) each of the third die stack and the fourth die stack to the secondary substrate.

20. The method of claim 16, wherein attaching the third die stack and the fourth die stack on the secondary substrate comprises electrically coupling, via first vertical wires, each of the dies of the third die stack and the fourth die stack to the secondary substrate, and wherein attaching the secondary substrate on the first die stack and the second die stack comprises electrically coupling, via second vertical wires, each of the dies of the first die stack and the second die stack to the secondary substrate.
